(19) United States
(12) Patent Application Publication
(10) Pub. No.: US 2010/0055620 A1
(43) Pub. Date: Mar. 4, 2010

(54) NANOSTRUCTURE FABRICATION

(75) Inventor: Sunghoon Kwon, Seoul (KR)

Correspondence Address: KNOBBE MARTENS OLSON & BEAR LLP, 2040 MAIN STREET, FOURTEENTH FLOOR, IRVINE, CA, 92614, US

(73) Assignee: Seoul National University Research and Development Business Foundation (SNU R&DB FOUNDATI, Seoul (KR)

(21) Appl. No.: 12/323,372

(22) Filed: Nov. 25, 2008

(30) Foreign Application Priority Data
Aug. 28, 2008 (KR) 10-2008-0084556

(51) Int. Cl. G03F 7/20; B05D 3/00; C23C 16/56; B05D 3/12; C23C 14/34

(52) U.S. Cl. 430/323; 427/331; 427/585; 427/355; 204/192.12; 977/887; 977/888; 977/890

(57) ABSTRACT

Techniques for fabricating nanostructures are provided. In one embodiment a method includes forming a multilayer stack including at least one pair of a structural layer and a sacrificial layer on a substrate, patterning the multilayer stack in order to fabricate a nanostructure, and releasing the nanostructure from the patterned multilayer stack.

### BACKGROUND

Recent developments in semiconductor technology have resulted in the reduced size of electronic component devices, particularly the width of wires in the devices. As a result, the importance of nanowires for electrically connecting devices is ever-increasing. Nanowires have a wide range of applications depending on relevant substances. For example, nanowires have been used in devices for emitting/receiving light (optical usage). Furthermore, nanowires have been added to composite materials (mechanical usage). Although nanowires can potentially be used in many fields, a limitation to their use is that conventional methods only allow nanostructures to be fabricated on a single surface of a base substrate.

### SUMMARY

In one embodiment a method for fabricating nanostructures is provided. The method includes forming a multilayer stack including at least one pair of a structural layer and a sacrificial layer on a substrate, patterning the multilayer stack in order to fabricate a nanostructure, and releasing the nanostructure from the patterned multilayer stack.

The Summary is provided to introduce a selection of concepts in a simplified form that are further described below in the Detailed Description. This Summary is not intended to identity key features or essential features of the claimed subject matter, nor is it intended to be used to limit the scope of the claimed subject matter.

### BRIEF DESCRIPTION OF THE DRAWINGS

FIG. 1 shows a side cross sectional view of an illustrative embodiment of a substrate on which a nanostructure is to be fabricated.

FIGS. 2A and 2B show side cross sectional views each of an illustrative embodiment of a substrate on which a sacrificial layer and a structural layer are formed on a top surface of the substrate.

FIGS. 3A to 3C show schematic diagrams each of an illustrative embodiment of patterning a multilayer stack.

FIG. 4 shows a side cross sectional view of an illustrative embodiment of a substrate on which a patterned multilayer stack is formed.

FIG. 5 shows a side cross sectional view of an illustrative embodiment of a substrate on which a sacrificial layer is etched away from a patterned multilayer stack to release nanostructures.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized and other changes may be made, without departing from the spirit or scope of the subject matter presented here. It will be readily understood that the components of the present disclosure, as generally described herein, and illustrated in the Figures, may be arranged, substituted, combined, and designed in a wide variety of different configurations, all of which are explicitly contemplated and make part of this disclosure.

In the following description, when it is said that a layer, substrate, area, region or other part are “on” or “above” another element it will be understood that the layer or substrate is positioned either directly on or above the another element or on or above the another element with one or more elements positioned between them. On the contrary, when it is said that a layer or substrate is “directly on” another element it will be understood that the layer or substrate is positioned directly on or above the another element.

The term “nanostructure” described hereinafter indicates nano-scaled structure such as nanoribbon, nanoline, nanotube and the combination thereof. Further, the nanostructure described hereinafter comprises various shapes of nanostructures.

In one embodiment a method for fabricating nanostructures includes forming a multilayer stack on a substrate. The multilayer stack includes at least one pair of a structural layer and a sacrificial layer. The method also includes patterning the multilayer stack in order to fabricate a nanostructure, and releasing the nanostructure from the patterned multilayer stack.

In forming the multilayer stack on the substrate, the structural layer and the sacrificial layer may be alternatively deposited.

The multilayer stack may be formed on the substrate by thermal oxidation, epitaxial growth, Chemical Vapor Deposition (CVD), or sputtering.

In patterning the multilayer stack, a pattern may be transferred to the multilayer stack by using photolithography, nanoimprint, or electron beam lithography. Both the structural and sacrificial layers of the multilayer stack may be etched according to the transferred pattern.

In releasing the nanostructure, the sacrificial layer may be removed by etching.

In removing the sacrificial layer, the sacrificial layer may be etched by wet etching.

The multilayer stack may include one or more pairs of the structural layer and the sacrificial layer.

In forming a multilayer stack, the structural layers and the sacrificial layers may be alternatively deposited on the substrate. The structural layers may have compositions different from each other.

The structural layer may include Si.

The sacrificial layer may include SiO₂.

In another embodiment a method for fabricating a nanostructure includes forming a plurality of pairs, each pair having a structural layer and a sacrificial layer. The pairs may be pasted such that the structural layers and the sacrificial layers are alternatively deposited to each other. The method also includes depositing the pasted pairs on a substrate, patterning the deposited pairs to fabricate multiple nanostructures, and releasing the multiple nanostructures from the patterned pairs.

The plurality of pairs may be formed by performing thermal oxidation, epitaxial growth, CVD, or sputtering.

In patterning the depositing pairs, a pattern may be transferred to the deposited pairs by photolithography, nanoimprint, or electron beam lithography. The deposited pairs may be etched according to the transferred pattern.

In releasing the multiple nanostructures, the sacrificial layers may be removed from the patterned pairs by etching.

In removing the sacrificial layer, the sacrificial layers may be etched by wet etching.

The structural layers may have different compositions.

The structural layers may include Si, and the sacrificial layers may include SiO₂.

Therefore, a plurality of nanostructures, each having a desired shape and size, can be fabricated through one patterning process.

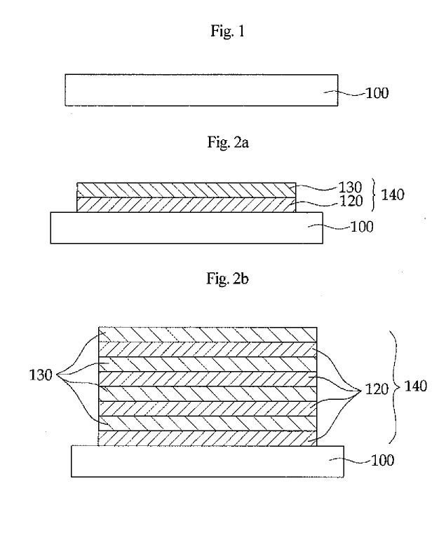

Hereinafter, a method for fabricating a nanostructure according to one illustrative embodiment will be described with reference to FIGS. 1 to 5. FIG. 1 shows a side cross sectional view of an illustrative embodiment of a substrate on which a nanostructure is to be fabricated. FIGS. 2A and 2B show side cross sectional views each of an illustrative embodiment of a substrate on which a sacrificial layer and a structural layer are formed on a top surface of the substrate.

As shown in FIG. 1, a substrate 100 on which a nanostructure is to be fabricated is prepared. The substrate 100 may be a semiconductor wafer, e.g., a silicon (Si) wafer. The substrate 100 may be formed using any of a variety of techniques capable of forming a substrate having a flat shape. For example, one suitable technique includes finely grinding ultrapure polycrystalline silicon, melting the finely ground ultrapure polycrystalline silicon in a heating furnace, and growing the silicon into a single crystal by, for example, a crystal pulling method. The grown cylinder-shaped silicon is then thinly cut. As a result the substrate 100 composed of the single crystal silicon is formed.

Next, as shown in FIGS. 2A and 2B, a sacrificial layer 120 and a structural layer 130 are formed on a top surface of the substrate 100 in sequence. Referring to FIG. 2A, a pair of the sacrificial layer 120 and the structural layer 130 is deposited on the substrate 100 so as to form a multilayer stack 140. The sacrificial layer 120 may be selectively etched to release the structural layer 130 in a subsequent process. The structural layer 130 may be formed into a nanostructure in a subsequent process.

According to another embodiment as shown in FIG. 2B, two or more pairs, each pair having the sacrificial layer 120 and the structural layer 130, are deposited on the substrate 100 so as to form the multilayer stack 140. The sacrificial layer 120 and the structural layer 130 may be alternatively deposited on the substrate 100. In a subsequent process, the sacrificial layer 120 may be selectively etched so as to release the nanostructure, which is formed from the structural layer 130.

The sacrificial layer 120 and the structural layer 130 may include SiO₂ and Si, respectively. In another example, the structural layer 130 and the sacrificial layer 120 may include germanium and germanium oxide, respectively. However, the compositions of the structural layer 130 and the sacrificial layer 120 are not limited to semiconductor materials and their oxides, and may be any material with which nanostructures may be fabricated in a subsequent process. The sacrificial layer 120 may include any material capable of being selectively etched while leaving the structural layer 130. The structural layer 130 may include any material capable of constituting the nanostructure. As shown in FIG. 2B, if the multilayer stack 140 includes a plurality of pairs, each having the sacrificial layer 120 and the structural layer 130, the structural layers 130 may be composed of different compositions from each other. Alternatively, some of the structural layers 130 may have compositions identical to each other.

The sacrificial layer 120 and the structural layer 130 can be fabricated using any of a variety of thin film fabrication techniques such as, by way of example, thermal oxidation, epitaxial growth, Chemical Vapor Deposition (CVD), and sputtering. In one embodiment, the sacrificial layer 120 composed of SiO₂ may be fabricated by a thermal oxidation method or an epitaxial growth method. The structural layer 130 composed of Si may be fabricated by a CVD method or a sputtering method, but the methods are not limited thereto.

According to the another embodiment, a plurality of pairs, each pair having the sacrificial layer 120 and the structural layer 130, may be pasted with each other, instead of alternatively depositing the sacrificial layers 120 and the structural layers 130 to form the multilayer stack 140 as described above in relation to FIG. 2B. For example, one surface of a silicon substrate may be oxidized by using any of a variety of suitable techniques such as, by way of example, thermal oxidation, epitaxial growth, CVD, or sputtering. As a result, the silicon substrate having one pair of surfaces, one composed of SiO₂ (sacrificial layer) and the other composed of Si (structural layer), can be formed. Accordingly, a plurality of these pairs is formed. Then, a Si surface of one pair is pasted with a SiO₂ surface of another pair. The pasted surface is heat-treated at approximately 900° C. or higher. The time duration of the heat treatment can be appropriately selected to prevent the pasted layers from being disassembled in subsequent processes. For example, the time duration of the heat treatment may be several hours at around 900° C., or is several minutes to several tens of minutes at 1200° C. The pasted plurality of pass each pair having the sacrificial layer 120 and the structural layer 130, are subsequently deposited on the substrate 100.

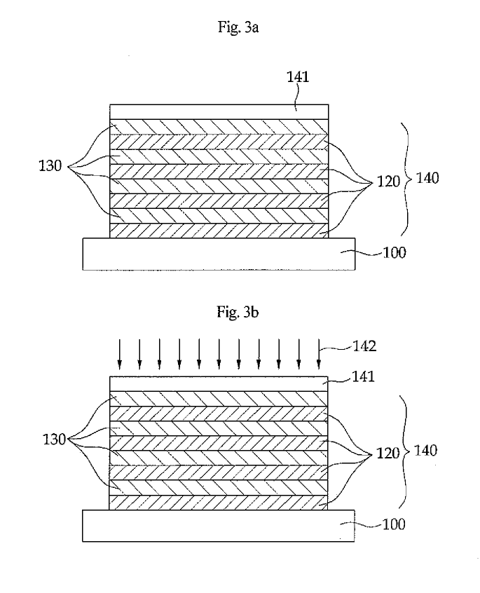

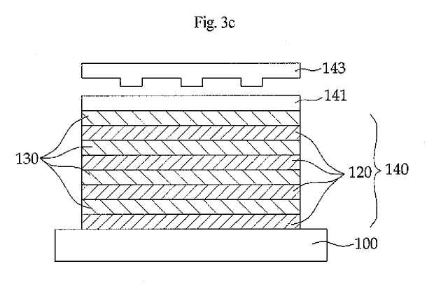

Then, the multi layer stack 140 formed on the substrate 100, for example, as shown in FIGS. 2A and 2B, is patterned. FIGS. 3A to 3C show schematic diagrams each of an illustrative embodiment of patterning the multilayer stack 140.

For example, patterning the multilayer stack 140 may include transferring a pattern to the multilayer stack 140 by photolithography or nanoimprint, but the transferring method is not limited thereto.

One illustrative embodiment in which lithography is used to pattern the multilayer stack 140 will be described hereinafter. Lithography may include photolithography or electron beam lithography, but the present disclosure is not limited thereto. As shown in FIGS. 3A and 3B, a photoresist 141 may be coated on the multilayer stack 140 using a coater. Then, a pattern is transferred to the photoresist 141 using, by way of example and not limitation, visible rays, ultraviolet rays, X-rays (for the photolithography), or an electron beam (for the electron beam lithography) 142. As one example, a light or electron beam may be irradiated to the photoresist 141 via a mask which is prepared to obtain nanostructures having a desired shape or size. By using the mask, a pattern having the desired shape or size may be transferred to the photoresist 141. Then, the substrate 100 is subjected to a Post Exposure Baking (PEB) process and a developing process.

According to another embodiment a nanoimprint may be used to transfer a pattern to the multilayer stack 140, as shown in FIG. 3C. In this case, the photoresist 141 is coated on the multilayer stack 140, and then a pattern is transferred to the photoresist 141 using, for example, a mold 143 having nano-sized protrusions. Then, the substrate 100 is subjected to the PEB process and developing process.

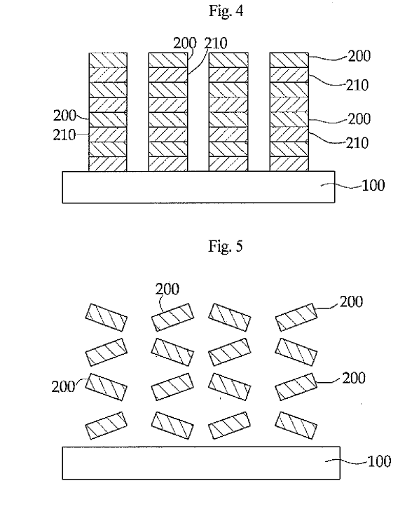

After the pattern transfer, PEB process, and developing process, the multilayer stack 140 may be etched according to the transferred pattern formed on the photoresist 141. FIG. 4 shows the resulting structure. In particular, FIG. 4 shows a side cross sectional view of an illustrative embodiment of a substrate on which a patterned multilayer stack is formed. For example, the etching used in the patterning process may be non-selective etching which etches both the sacrificial layer 120 and the structural layer 130 according to the transferred pattern. Non-selective etching etches desired portions of the sacrificial layer 120 and the structural layer 130 from the top of the multilayer stack 140 to the top surface of the substrate 100. As the result of the complete etching of desired portions of the multilayer stack 140, a multilayer stack 140 having a desired shape is left on the substrate 100, as shown FIG. 4.

The etching may be dry etching or wet etching, but is not limited thereto. Further, any non-selective etching method, which can etch both the sacrificial layer 120 and the structural layer 130 comprised in the multilayer stack 140, can be used. For example, HF, which is used for the etching of silicon dioxide, and the mixture of HF, HNO₃ and CH₃COOH+O₂, which is used for the etching of Si, may be used to perform the wet etching as the non-selective etching.

The non-etched parts of the structural layers 130 of the multilayer stack 140 become nanostructures 200. The non-etched parts among the sacrificial layers 120 of the multilayer stack 140 become sacrificial structures 210. The sacrificial structures 210 may then be removed by, for example, selective etching, which will be described later. The top views of the nanostructures 200 are determined by the transferred pattern. The widths of the nanostructures 200 are determined by the resolution of the transferred pattern. The heights of the nanostructures 200 are determined by the heights of the structural layer 130. Therefore, the nanostructures 200 having a desired shape, width, and height may be produced by controlling the shape and resolution of the transferred pattern and/or the height of the structural layer 130.

In some embodiments, a photoresist polymer may be left on the multilayer stack 140 after non-selective etching. Thus, in these embodiments, a process for removing the remaining the residue polymer may be further performed. However, the removal of the residue polymer may be simultaneously conducted with the selective etching to be described later.

FIG. 5 shows a side cross sectional view of an illustrative embodiment of a substrate on which a sacrificial layer is removed from the patterned multilayer stack and nanostructures are released. As shown in FIG. 5, the nanostructures 200 are released from the substrate 100. The sacrificial layers 120 included in the multilayer stack 140 are removed so as to obtain the nanostructures 200. For example, the sacrificial layer 120 may be selectively etched away from the patterned multilayer stack 140. As a result, the nanostructures 200 composed of the structural layers 130 are released. The etching may be wet etching. When wet etching is used, the released nanostructures 200 may be floated in the etching solution. When the sacrificial layer 120 is composed of SiO₂, the etching solution may include HF or the mixture of HF and NH₄F. However, the composition of the solution is not limited thereto.

The nanostructures fabricated according to some embodiments described herein may be applied to small-sized structures, such as solar cells, textiles, bio sensors, and the like. By way of example, the solar cell may be manufactured in the form of a plastic cover or paint using the nanostructure described above. The solar cell may be used as a coating agent so that it may be coated on any surface which is exposed to sunlight. As example of the surface, there is the exterior of a house or an automobile. Further, the nanostructure may be used for manufacturing the textile. For example, the nanostructure may be fabricated in the form of a cobweb. The textile having such nanostructures possesses a thin and break-resistant property. Furthermore, the nanostructure may be used for the nano-bio sensor which may be directly inserted in a sensing object. Although such applications are introduced herein, the present disclosure is not limited thereto.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A method for fabricating a nanostructure, comprising:
forming on a substrate a multilayer stack including at least one pair of a structural layer and a sacrificial layer;
patterning the multilayer stack in order to fabricate a nanostructure; and
releasing the nanostructure from the patterned multilayer stack.

2. The method of claim 1, wherein forming the multilayer stack on the substrate comprises alternatively depositing the structural layer and the sacrificial layer on the substrate.

3. The method of claim 1, wherein forming the multilayer stack on the substrate is performed by thermal oxidation, epitaxial growth, Chemical Vapor Deposition (CVD), or sputtering.

4. The method of claim 1, wherein patterning the multilayer stack comprises:
transferring a pattern to the multilayer stack by using photolithography, nanoimprint, or electron beam lithography; and
etching both the structural and sacrificial layers of the multilayer stack according to the transferred pattern.

5. The method of claim 1, wherein releasing the nanostructure comprises removing the sacrificial layer by etching.

6. The method of claim 5, removing the sacrificial layer comprises etching the sacrificial layer by wet etching.

7. The method of claim 1, wherein the multilayer stack comprises a plurality of pairs, each having the structural layer and the sacrificial layer.

8. The method of claim 7, wherein forming the multilayer stack on the substrate comprises alternatively depositing the structural layers and the sacrificial layers on the substrate, and wherein the structural layers have compositions different from each other.

9. The method of claim 1, wherein the structural layer includes Si.

10. The method of claim 1, wherein the sacrificial layer includes SiO₂.

11. A method for fabricating a nanostructure, comprising:
forming a plurality of pairs, each pair having a structural layer and a sacrificial layer;
pasting the pairs such that the structural layers and the sacrificial layers are alternatively deposited to each other;
depositing the pasted pairs on a substrate;
patterning the deposited pairs to fabricate multiple nanostructures; and
releasing the multiple nanostructures from the patterned pairs.

12. The method of claim 11, wherein forming the plurality of pairs is performed by thermal oxidation, epitaxial growth, CVD, or sputtering.

13. The method of claim 11, wherein patterning the depositing pairs comprises:
transferring a pattern to the deposited pairs by photolithography, nanoimprint, or electron beam lithography; and
etching the deposited pairs according to the transferred pattern.

14. The method of claim 11, wherein releasing the multiple nanostructures comprises removing the sacrificial layers from the patterned pairs by etching.

15. The method of claim 14, removing the sacrificial layer comprises etching the sacrificial layers by wet etching.

16. The method of claim 11, wherein the structural layers have different compositions.

17. The method of claim 11, wherein the structural layers include Si, and the sacrificial layers include SiO₂.
